(19) United States
(12) Patent Application Publication
(10) Pub. No.: US 2023/0187357 A1
(43) Pub. Date: Jun. 15, 2023

(54) SEMICONDUCTOR DEVICE

(71) Applicant: Mitsubishi Electric Corporation, Tokyo (JP)

(72) Inventors: Koji TANAKA, Tokyo (JP); Kazuya KONISHI, Tokyo (JP)

(73) Assignee: Mitsubishi Electric Corporation, Tokyo (JP)

(21) Appl. No.: 17/938,309

(22) Filed: Oct. 5, 2022

(30) Foreign Application Priority Data
Dec. 14, 2021 (JP) 2021-202627

(51) Int. Cl. H01L 23/535; H01L 23/31; H01L 23/532; H01L 29/739

(52) U.S. Cl. CPC H01L 23/535; H01L 23/3171; H01L 23/3192; H01L 23/53238; H01L 29/7397

(57) ABSTRACT

A semiconductor device includes: an emitter electrode being a metal electrode disposed on a semiconductor substrate; a first passivation film made of a material other than an organic resin, and covering a portion of the emitter electrode; and a second passivation film made of the organic resin, and covering a portion of the emitter electrode via the first passivation film. A copper electrode connected to a portion of the emitter electrode not covered with the first passivation film and including copper as a major component is disposed over the emitter electrode. The second passivation film and the copper electrode are spaced apart.

### BACKGROUND OF THE INVENTION

### Field of the Invention

The present disclosure relates to semiconductor devices.

### Description of the Background Art

A semiconductor device having a configuration in which an electrode including copper (Cu) as a major component and a protective film made of an organic resin are arranged over a semiconductor chip to reduce resistance of the electrode, improve heat dissipation, and improve reliability against thermal stress has been known (e.g., Japanese Patent Application Laid-Open No. 2006-86378).

The protective film made of the organic resin is often a member essential to secure moisture resistance and electrostatic resistance of the semiconductor chip. The semiconductor device disclosed in Japanese Patent Application Laid-Open No. 2006-86378 has a configuration in which the electrode including copper as the major component and the protective film made of the organic resin are in contact with each other, so that diffusion of copper of the electrode into the organic resin of the protective film during high temperature operation of the semiconductor device to form an altered layer in the protective film to thereby reduce reliability of the semiconductor device is a concern.

### SUMMARY

It is an object of the present disclosure to improve reliability of a semiconductor device including an electrode including copper as a major component and a protective film made of an organic resin.

A semiconductor device according to the present disclosure includes: a metal electrode disposed on a semiconductor substrate; a first passivation film made of a material other than an organic resin, and covering a portion of the metal electrode; a second passivation film made of the organic resin, and covering a portion of the metal electrode via the first passivation film; and a copper electrode including copper as a major component, disposed over the metal electrode, and connected to a portion of the metal electrode not covered with the first passivation film. The second passivation film and the copper electrode are spaced apart.

According to the present disclosure, the second passivation film made of the organic resin is spaced apart from the copper electrode, so that diffusion of copper into the second passivation film to form an altered layer is prevented, and reliability of the semiconductor device can be improved.

These and other objects, features, aspects and advantages of the present invention will become more apparent from the following detailed description of the present invention when taken in conjunction with the accompanying drawings.

### BRIEF DESCRIPTION OF THE DRAWINGS

FIG. 1 illustrates a configuration of a semiconductor device according to Embodiment 1;

FIG. 2 illustrates a modification of the semiconductor device according to Embodiment 1; and

FIG. 3 illustrates a configuration of a semiconductor device according to Embodiment 2.

### DESCRIPTION OF THE PREFERRED EMBODIMENTS

While an insulated gate bipolar transistor (IGBT) is shown as an example of a semiconductor device in each of embodiments below, the semiconductor device may be a diode, a reverse-conducting IGBT (RC-IGBT), a metal-oxide-semiconductor field-effect transistor (MOSFET), and the like. Description will be made below based on the assumption that a first conductivity type is an N type, and a second conductivity type is a P type, but the first conductivity type may be the P type, and the second conductivity type may be the N type.

### <Embodiment 1>

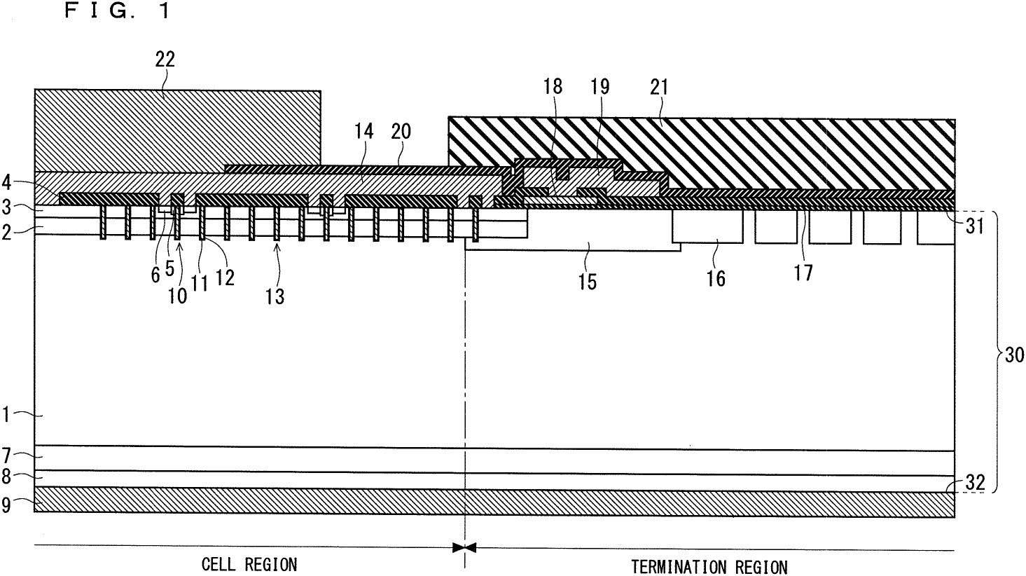

FIG. 1 illustrates a configuration of a semiconductor device according to Embodiment 1. The semiconductor device according to Embodiment 1 includes a cell region where an IGBT cell is formed and a termination region located outside the cell region, and FIG. 1 illustrates a cross section of a portion at a boundary between the cell region and the termination region.

The semiconductor device is formed using a semiconductor substrate 30 having a first main surface 31 and a second main surface 32. The semiconductor substrate 30 includes a drift layer 1 of the first conductivity type between the first main surface 31 and the second main surface 32. A material of the semiconductor substrate 30 may be typical silicon (Si), or may be a wide bandgap semiconductor, such as silicon carbide (SiC). In a case where the wide bandgap semiconductor is used, a semiconductor device capable of high voltage, high current, and high temperature operation can be obtained compared with a case where silicon is used.

In the cell region, a carrier storage layer 2 of the first conductivity type having a higher peak impurity concentration than the drift layer 1 is formed on a side of the first main surface 31 of the drift layer 1, and a base layer 3 of the second conductivity type is further formed in a surface portion on a side of the first main surface 31 of the semiconductor substrate 30. In a surface portion of the base layer 3, an emitter layer 5 of the first conductivity type and a contact layer 6 of the second conductivity type having a higher peak impurity concentration than the base layer 3 are selectively formed.

In the first main surface 31 of the semiconductor substrate 30, an active trench 10 reaching the drift layer 1 through the emitter layer 5, the base layer 3, and the carrier storage layer 2 and a dummy trench 13 reaching the drift layer 1 through the base layer 3 and the carrier storage layer 2 in a region free of the emitter layer 5 are formed. The dummy trench 13 is formed to surround the active trench 10. A gate electrode 12 is embedded in each of the active trench 10 and the dummy trench 13 via a gate insulating film 11. The gate electrode 12 embedded in the dummy trench 13 is a dummy electrode not contributing to switching on and off of an IGBT.

An interlayer insulating film 4 to cover the active trench 10 and the dummy trench 13 is formed on the first main surface 31 of the semiconductor substrate. An emitter electrode 14 being a metal electrode made of metal, such as aluminum (Al), is formed on the interlayer insulating film 4. The emitter electrode 14 is connected to the emitter layer 5 and the contact layer 6 via a contact hole formed in the interlayer insulating film 4.

A buffer layer 7 of the first conductivity type having a higher peak impurity concentration than the drift layer 1 is formed on a side of the second main surface 32 of the drift layer 1. A collector layer 8 of the second conductivity type is further formed in a surface portion on a side of the second main surface 32 of the semiconductor substrate 30. A collector electrode 9 connected to the collector layer 8 is formed on the second main surface 32 of the semiconductor substrate. The buffer layer 7, the collector layer 8, and the collector electrode 9 are formed not only in the cell region but also in the peripheral region.

On the other hand, in the termination region, a well layer 15 of the second conductivity type having a greater depth than the active trench 10 and the dummy trench 13 and a resurf layer 16 of the second conductivity type located outside the well layer 15 are formed in a surface portion on a side of the first main surface 31 of the semiconductor substrate 30. A field oxide film 17 is formed on the first main surface 31 of the semiconductor substrate 30 to cover the well layer 15 and the resurf layer 16. Gate wiring 18 is formed on the field oxide film 17 above the well layer 15. The gate wiring 18 is covered with the interlayer insulating film 4 extending from the cell region, and a gate runner 19 connected to the gate wiring 18 via a contact hole formed in the interlayer insulating film 4 is formed above the gate wiring 18.

In the semiconductor device according to Embodiment 1, a first passivation film 20 made of a material other than an organic resin is formed to cover a portion of the emitter electrode 14 being the metal electrode and the gate runner 19. Furthermore, a second passivation film 21 made of the organic resin is formed on the first passivation film 20 to cover a portion of the emitter electrode 14 via the first passivation film 20. The first passivation film 20 is made of a material into which copper is less likely to be diffused, and a silicon nitride (SiN) film is used as a material of the first passivation film 20 in the present embodiment. The material of the first passivation film 20 is not limited to the silicon nitride film, and may be a semi-insulating film including nitrogen (N), an oxide film including silicon (Si), and the like.

A copper electrode 22 including copper as a major component is formed over the emitter electrode 14. The copper electrode 22 is connected to a portion of the emitter electrode 14 not covered with the first passivation film 20, and an end of the copper electrode 22 rides on the first passivation film 20. The second passivation film 21 and the copper electrode 22 are spaced apart.

The passivation film made of the organic resin is typically essential to secure moisture resistance and electrostatic resistance of the semiconductor device. In a case where the passivation film made of the organic resin is in contact with the copper electrode, however, diffusion of copper into the organic resin of the passivation film during high temperature operation of the semiconductor device to form an altered layer to thereby reduce reliability of the semiconductor device is a concern.

In the semiconductor device according to Embodiment 1, the second passivation film 21 made of the organic resin and the copper electrode 22 are spaced apart, so that the above-mentioned problem does not arise. A portion in which the second passivation film 21 and the copper electrode 22 are spaced apart is covered with the first passivation film 20 to prevent reduction in moisture resistance and electrostatic resistance of the semiconductor device caused by spacing the second passivation film 21 and the copper electrode 22 apart. Reliability of the semiconductor device is thereby improved.

If the second passivation film 21 and the copper electrode 22 are closely spaced, however, when the copper electrode 22 is deformed by power applied in a process of bonding, such as wire bonding, the deformed copper electrode 22 might be in contact with the second passivation film 21. Spacing between the second passivation film 21 and the copper electrode 22 is thus preferably wide to the extent that, when the copper electrode 22 is deformed, the deformed copper electrode 22 is not in contact with the second passivation film 21, and, specifically, is preferably equal to or greater than the thickness of the copper electrode 22.

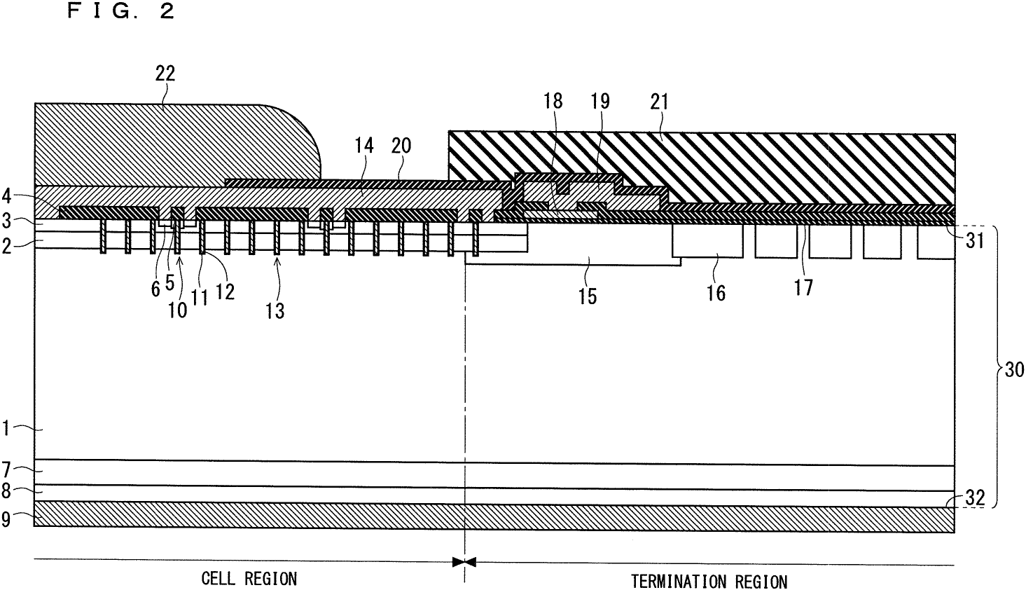

The copper electrode 22 disposed over the emitter electrode 14 can be formed by electrolytic plating or electroless plating. When the copper electrode 22 is formed by electrolytic plating, a plated film to be the copper electrode 22 is required to be formed over the entire surface of the semiconductor substrate 30 and patterned by etching using a resist mask, so that an end surface of the copper electrode 22 is planar when viewed in cross section as illustrated in FIG. 1. On the other hand, when the copper electrode 22 is formed by electroless plating, the plated film to be the copper electrode 22 is selectively formed over a portion of the emitter electrode 14 made of metal exposed from the first passivation film 20 and grows, and is thus not required to be patterned, so that the end surface of the copper electrode 22 is curved (arcuate) when viewed in cross section as illustrated in FIG. 2.

While FIG. 1 illustrates an example in which the first passivation film 20 and the second passivation film 21 are arranged in the portion at the boundary between the cell region and the termination region of the semiconductor device, the first passivation film 20 and the second passivation film 21 may be arranged between a plurality of IGBT cells in the cell region, for example. In this case, an effect similar to the above-mentioned effect can be obtained by spacing the second passivation film 21 and the copper electrode 22 apart in the cell region.

### <Embodiment 2>

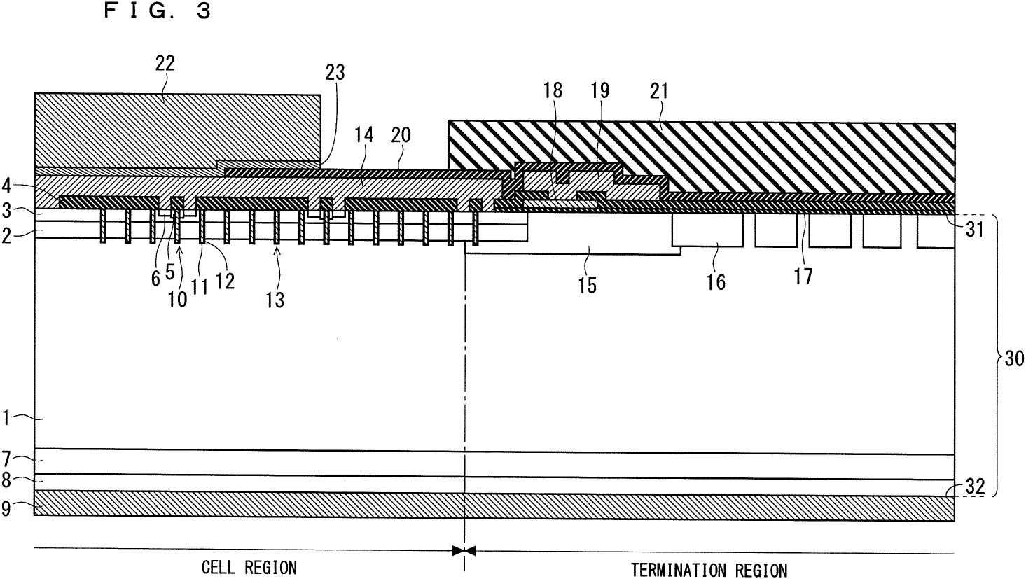

FIG. 3 illustrates a configuration of a semiconductor device according to Embodiment 2. The semiconductor device in FIG. 3 has a configuration in which a barrier metal 23 to prevent diffusion of copper is disposed on a bottom surface of the copper electrode 22 in the configuration in FIG. 1. The barrier metal 23 is thus interposed between the copper electrode 22 and the emitter electrode 14 and between the copper electrode 22 and the first passivation film 20. Ta, TaN, Ti, TiN, W, TiW, and the like can be used as a material of the barrier metal 23. The other components are similar to those in FIG. 1, so that description thereof is omitted.

The barrier metal 23 prevents diffusion of copper of the copper electrode 22 into the emitter electrode 14, the interlayer insulating film 4, and the like to further improve reliability of the semiconductor device.

Embodiments can freely be combined with each other, and can be modified or omitted as appropriate.

While the invention has been shown and described in detail, the foregoing description is in all aspects illustrative and not restrictive. It is therefore understood that numerous modifications and variations can be devised without departing from the scope of the invention.

What is claimed is:

1. A semiconductor device comprising:
a metal electrode disposed on a semiconductor substrate;
a first passivation film made of a material other than an organic resin, and covering a portion of the metal electrode;
a second passivation film made of the organic resin, and covering a portion of the metal electrode via the first passivation film; and
a copper electrode comprising copper as a major component, the copper electrode being disposed over the metal electrode, and connected to a portion of the metal electrode not covered with the first passivation film, wherein
the second passivation film and the copper electrode are spaced apart.

2. The semiconductor device according to claim 1, wherein
spacing between the second passivation film and the copper electrode is equal to or greater than a thickness of the copper electrode.

3. The semiconductor device according to claim 1, wherein
an end surface of the copper electrode is planar when viewed in cross section.

4. The semiconductor device according to claim 1, wherein
an end surface of the copper electrode is curved when viewed in cross section.

5. The semiconductor device according to claim 1, wherein
a barrier metal to prevent diffusion of copper is interposed between the copper electrode and the metal electrode.

6. The semiconductor device according to claim 1, wherein
an end of the copper electrode rides on the first passivation film.

7. The semiconductor device according to claim 1, wherein
a material of the first passivation film is any of a nitride film comprising silicon, an oxide film comprising silicon, and a semi-insulating film comprising nitrogen.
